(19) United States
(12) Patent Application Publication
(10) Pub. No.: US 2024/0162254 A1
(43) Pub. Date: May 16, 2024

(54) SOLID-STATE IMAGING DEVICE AND ELECTRONIC DEVICE

(71) Applicant: SONY SEMICONDUCTOR SOLUTIONS CORPORATION, Kanagawa (JP)

(72) Inventor: Ryosuke NAKAMURA, Kanagawa (JP)

(73) Assignee: SONY SEMICONDUCTOR SOLUTIONS CORPORATION, Kanagawa (JP)

(21) Appl. No.: 18/550,738

(22) PCT Filed: Jan. 20, 2022
(86) PCT No.: PCT/JP2022/001917

§ 371 Date: Sep. 15, 2023

(30) Foreign Application Priority Data
Mar. 25, 2021 (JP) 2021-051073

(51) Int. Cl. H01L 27/146; H04N 25/616; H04N 25/778

(52) U.S. Cl. CPC H01L 27/14605; H01L 27/14627; H04N 25/778; H04N 25/616

(57) ABSTRACT

The present technology relates to a solid-state imaging device and an electronic device enabling improvement of an SN characteristic. A solid-state imaging device includes a pixel array unit provided with multiple unit pixels. Each of the unit pixels includes: a small pixel having a first photoelectric conversion unit and a first on-chip lens configured to allow light to enter the first photoelectric conversion unit; and a large pixel having a second photoelectric conversion unit divided into multiple regions, and a second on-chip lens that can condense more light than the first on-chip lens and allows light to enter the second photoelectric conversion unit. The present technology may be applied to a CMOS image sensor.

### TECHNICAL FIELD

The present technology relates to a solid-state imaging device and an electronic device, and particularly relates to a solid-state imaging device and an electronic device capable of improving an SN characteristic.

### BACKGROUND ART

As a solid-state imaging device, there is known a complementary metal oxide semiconductor (CMOS) solid-state imaging device (hereinafter, referred to as a CMOS image sensor) that can be manufactured by a process similar to that of a CMOS integrated circuit.

In the CMOS image sensor, an active structure having an amplification function for every pixel can be easily made by a refinement technology associated with the CMOS process. Furthermore, there is an advantage that a peripheral circuit unit such as a signal processing circuit that processes a signal output from the CMOS image sensor and each pixel of a pixel array unit can be integrated on the same chip (substrate) as the pixel array unit.

Therefore, attention has been paid to the CMOS image sensor, and more research and development have been made regarding the CMOS image sensor.

For example, as a dynamic range expansion technique, a technique has been proposed in which a voltage applied to a transfer gate that transfers charges accumulated in a photodiode by time division as represented by water gate transfer is controlled to perform reading a plurality of times during an exposure period (see, for example, Patent Document 1).

Furthermore, there have also been proposed a technique of expanding a dynamic range by applying a space division method (see, for example, Patent Document 2), and a dynamic expansion technique in which a memory is provided in a pixel called a lateral overflow integration capacitor (LOFIC) to directly increase an amount of charge to be handled (see, for example, Patent Document 3).

Moreover, as a dynamic expansion technique compatible with light emitting diode (LED) flicker suppression, a technique has also been proposed in which a large pixel and a small pixel having different sensitivities are provided for a unit pixel, and signal processing is performed using a difference in sensitivity between the pixels (see, for example, Patent Document 4).

### CITATION LIST

### Patent Document

Patent Document 1: Japanese Patent Application Laid-Open No. 2008-99158
Patent Document 2: Japanese Patent Application Laid-Open No. 2006-253876
Patent Document 3: Japanese Patent Application Laid-Open No. 2005-328493
Patent Document 4: Japanese Patent Application Laid-Open No. 2017-163010

### SUMMARY OF THE INVENTION

### Problems to be Solved by the Invention

Meanwhile, as in Patent Document 4, there is a high dynamic range technology in which a unit pixel has a large pixel and a small pixel having different sensitivities, and signal processing is performed using a difference in sensitivity between these pixels.

In the high dynamic range technology, there is a technique of performing, in addition to dual gain reading using the large pixel, reading three times during a 1H period in which charges overflowing from the small pixel is stored, in a capacitance in the pixel, and reading is performed.

In such a technique, a final pixel signal, that is, a pixel value of a pixel of an image is calculated on the basis of signals obtained by the three times of reading.

At this time, the pixel value is calculated using a signal read from the large pixel up to predetermined illuminance, and the pixel value is calculated using a signal read from the small pixel at illuminance higher than the predetermined illuminance. Furthermore, at the predetermined illuminance, the pixel value is calculated using both a signal used at illuminance lower than the predetermined illuminance and a signal used at illuminance higher than the predetermined illuminance. The illuminance at which such two signals are used to calculate the pixel value is also called a connection point.

However, in the technique described above, it has been difficult to obtain a good signal to noise (SN) characteristic, that is, a good SN ratio at the illuminance serving as the connection point.

For example, in the small pixel, double data sampling (DDS)-driven reading is adopted in order to handle charges accumulated in the capacitance in the pixel. However, in a case where charges are accumulated in the capacitance in the pixel, charges are accumulated directly in floating diffusion (FD). Therefore, a correlated double sampling (CDS) method cannot be adopted, and a dark current and a fixed pattern noise (FPN) cannot be removed, so that the SN characteristic at the connection point is deteriorated.

The present technology has been made in view of such a condition, and is intended to improve an SN characteristic.

### Solutions to Problems

A solid-state imaging device according to a first aspect of the present technology includes a pixel array unit provided with multiple unit pixels, in which each of the unit pixels includes: a small pixel having a first photoelectric conversion unit and a first on-chip lens configured to allow light to enter the first photoelectric conversion unit; and a large pixel having a second photoelectric conversion unit divided into multiple regions, and a second on-chip lens capable of condensing more light than the first on-chip lens, the second on-chip lens being configured to allow light to enter the second photoelectric conversion unit.

In the first aspect of the present technology, a pixel array unit provided with multiple unit pixels is provided, and each of the unit pixels is provided with: a small pixel having a first photoelectric conversion unit and a first on-chip lens configured to allow light to enter the first photoelectric conversion unit; and a large pixel having a second photoelectric conversion unit divided into multiple regions, and a second on-chip lens that can condense more light than the first on-chip lens and allows light to enter the second photoelectric conversion unit.

Furthermore, an electronic device of a second aspect of the present technology is an electronic device including the solid-state imaging device of the first aspect of the present technology.

### BRIEF DESCRIPTION OF DRAWINGS

FIG. 1 is a diagram illustrating a configuration example of a CMOS image sensor.

FIG. 2 is a view illustrating a configuration example of a unit pixel.

FIG. 3 is a view illustrating another configuration example of the unit pixel.

FIG. 4 is a view illustrating another configuration example of the unit pixel.

FIG. 5 is a view illustrating another configuration example of the unit pixel.

FIG. 6 is a view illustrating another configuration example of the unit pixel.

FIG. 7 is a view illustrating another configuration example of the unit pixel.

FIG. 8 is a view illustrating another configuration example of the unit pixel.

FIG. 9 is a diagram illustrating a circuit configuration example of the unit pixel.

FIG. 10 is a diagram illustrating another circuit configuration example of the unit pixel.

FIG. 11 is a diagram for explaining a drive example of the unit pixel.

FIG. 12 is a diagram illustrating a configuration example of an imaging device.

FIG. 13 is a diagram illustrating a usage example of an image sensor.

FIG. 14 is a block diagram illustrating an example of a schematic configuration of a vehicle control system.

FIG. 15 is an explanatory diagram illustrating an example of installation positions of an outside-vehicle information detecting section and imaging sections.

### MODE FOR CARRYING OUT THE INVENTION

Hereinafter, embodiments to which the present technology is applied will be described with reference to the drawings.

### First Embodiment

<Configuration Example of CMOS Image Sensor>

The present technology is to enable improvement of an SN characteristic at a connection point by improving a saturation signal amount of a large pixel, in an image sensor having multiple pixels such as a large pixel and a small pixel in a unit pixel and having a capacitance in a pixel of FD accumulation.

For example, in the present technology, by dividing a photodiode provided in the large pixel into multiple regions such as four regions and making a region of a PN junction portion larger, a stronger electric field can be obtained, and as a result, a saturation signal amount can be increased. Note that the large pixel referred to herein is a pixel having a large size of the photodiode, and is mainly used for imaging characteristics of a low illuminance region, that is, used for imaging of a low illuminance region.

Furthermore, in the present technology, transfer capability can also be improved by providing multiple transfer gates which are for transferring charges obtained by the photodiode into the large pixel. As a result, an amount of charges (signal amount) that can be read in the large pixel can be further increased, and as a result, the saturation signal amount can be increased.

In this way, according to the present technology, since the saturation signal amount of the large pixel can be improved, illuminance serving as the connection point can be made higher illuminance. As the illuminance is higher, an influence of noise on a signal decreases, which can result in improvement of the SN characteristic at the connection point.

Hereinafter, more specific embodiments to which the present technology is applied will be described.

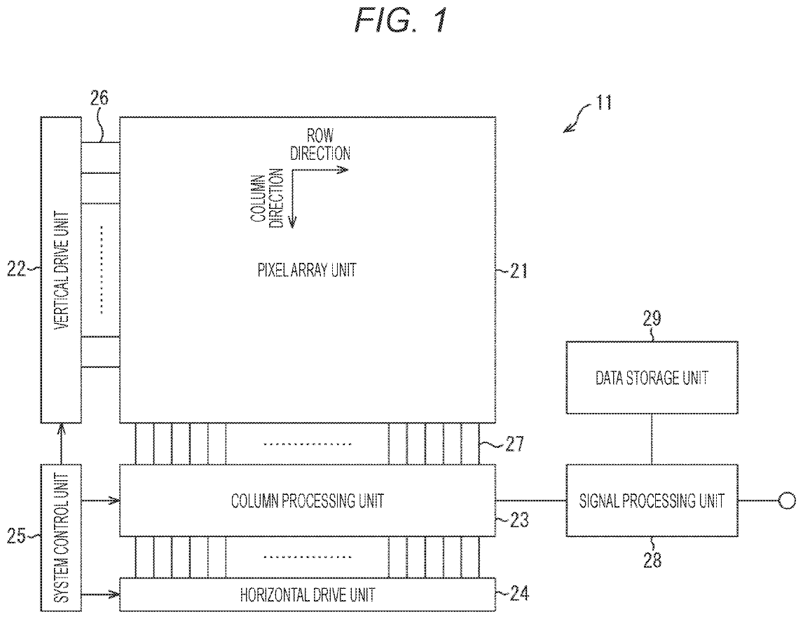

FIG. 1 is a diagram illustrating a configuration example of a CMOS image sensor, which is a solid-state imaging device to which the present technology is applied.

Here, the CMOS image sensor is an image sensor (solid-state imaging element) created by applying or partially using a CMOS process. For example, the solid-state imaging device is a back-illuminated CMOS image sensor or the like.

A CMOS image sensor 11 has a configuration including a pixel array unit 21 formed on a semiconductor substrate (chip) (not illustrated), and a peripheral circuit unit integrated on a semiconductor substrate same as that for the pixel array unit 21.

For example, the peripheral circuit unit has a vertical drive unit 22, a column processing unit 23, a horizontal drive unit 24, and a system control unit 25.

Moreover, the CMOS image sensor 11 has a signal processing unit 28 and a data storage unit 29. The signal processing unit 28 and the data storage unit 29 may be provided on a semiconductor substrate constituting the CMOS image sensor 11, or may be provided on a substrate different from the semiconductor substrate constituting the CMOS image sensor 11.

The pixel array unit 21 has a configuration in which multiple unit pixels (hereinafter, may be simply described as pixels) having a photoelectric conversion unit that generates and accumulates charges according to an amount of received light are two-dimensionally arranged in a row direction and a column direction, that is, in a matrix shape.

Here, the row direction is an arrangement direction (horizontal direction) of pixels in a pixel row, that is, a lateral direction in the figure, and the column direction is an arrangement direction (perpendicular direction) of pixels in a pixel column, that is, a vertical direction in the figure.

In the pixel array unit 21, a pixel drive line 26 is wired along the row direction for every pixel row, and a vertical signal line 27 is wired along the column direction for every pixel column with respect to the matrix-shaped pixel array. The pixel drive line 26 is a signal line for supplying a drive signal (control signal) for driving the pixel, such as driving when a signal is read from the pixel. One end of the pixel drive line 26 is connected to an output end corresponding to each row of the vertical drive unit 22.

Note that, here, one pixel drive line 26 is drawn for one pixel row in order to make the figure easily viewable, but multiple pixel drive lines 26 are actually wired for one pixel row.

The vertical drive unit 22 includes, for example, a shift register, an address decoder, and the like, and simultaneously drives each of all pixels in the pixel array unit 21 or drives the pixels in the pixel array unit 21 on a row-by-row basis.

For example, the vertical drive unit 22 has a configuration including two scanning systems of a read scanning system and a sweep scanning system.

The read scanning system selectively scans the unit pixels in the pixel array unit 21 sequentially on a row-by-row basis in order to read signals from the unit pixels. The signal read from the unit pixel is an analog signal.

The sweep scanning system performs sweep scanning at a predetermined timing on a read row on which read scanning is performed by the read scanning system. When the sweep scanning is performed by the sweep scanning system, an unnecessary charge is swept from the photoelectric conversion unit of the unit pixel in the read row. As a result, the photoelectric conversion unit is reset.

A signal output from each unit pixel of the pixel row selectively scanned by the vertical drive unit 22 is input to the column processing unit 23 via the vertical signal line 27 for every pixel column.

The column processing unit 23 performs predetermined signal processing on the signal supplied from each pixel of the selected row via the vertical signal line 27 for every pixel column of the pixel array unit 21, and temporarily holds the pixel signal that has been subjected to the signal processing.

For example, the column processing unit 23 performs noise removal processing, correlated double sampling (CDS) processing, DDS processing, analog to digital (AD) conversion processing, and the like as the signal processing. For example, in the CDS processing, fixed pattern noise unique to the pixel, such as reset noise or threshold variation of an amplification transistor in the pixel, is removed.

The horizontal drive unit 24 includes a shift register, an address decoder, and the like, and sequentially selects a unit circuit corresponding to a pixel column of the column processing unit 23. When the selective scanning is performed by the horizontal drive unit 24, pixel signals subjected to the signal processing for every unit circuit in the column processing unit 23 are sequentially output to the signal processing unit 28.

The system control unit 25 includes a timing generator that generates various timing signals, and the like, and performs drive control of the vertical drive unit 22, the column processing unit 23, the horizontal drive unit 24, and the like on the basis of the generated timing signals.

The signal processing unit 28 has at least an arithmetic processing function, and performs various types of signal processing such as arithmetic processing on a pixel signal output from the column processing unit 23. When the signal processing is performed in the signal processing unit 28, the data storage unit 29 temporarily stores data necessary for the processing.

<Configuration Example of Unit Pixel>

Next, a configuration example of the unit pixel provided in the pixel array unit 21 will be described.

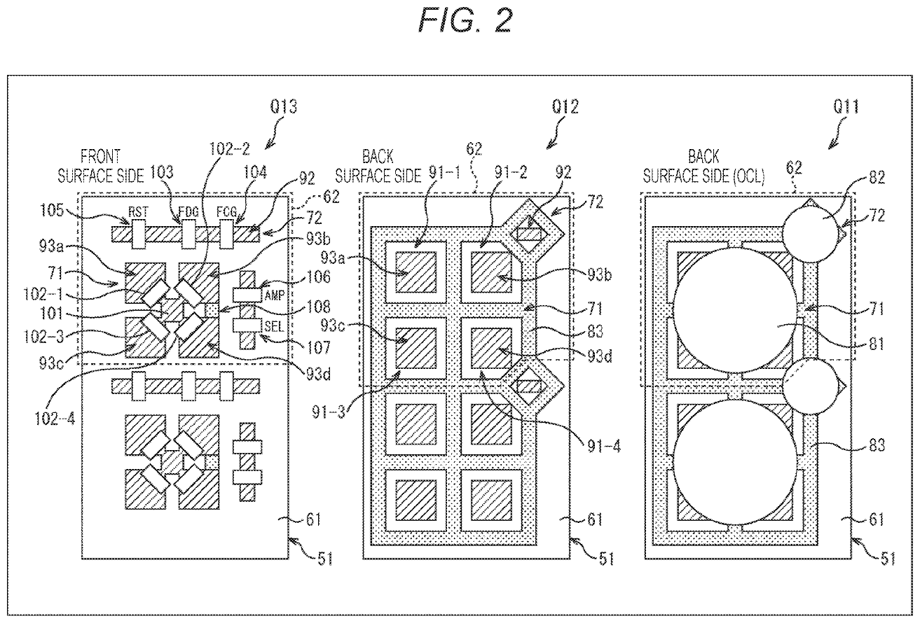

For example, a portion of the unit pixel provided in the pixel array unit 21 is as illustrated in FIG. 2 when viewed from a direction perpendicular to a surface of the semiconductor substrate on which the pixel array unit 21 is formed.

A portion indicated by Arrow Q11 in FIG. 2 indicates a view of a back surface side of a semiconductor substrate 51 provided with the pixel array unit 21, as viewed from a direction perpendicular to the surface of the semiconductor substrate 51.

Here, the back surface of the semiconductor substrate 51 is a surface on a side where light enters the pixel array unit 21 among surfaces of the semiconductor substrate 51.

In this example, for example, the semiconductor substrate 51 is a P-type semiconductor substrate having a P-well region 61, and a unit pixel 62 is formed by a partial region or the like of the semiconductor substrate 51.

In particular, here, the unit pixel 62 includes a large pixel 71 that is a pixel larger in size and a small pixel 72 that is smaller in size than the large pixel 71, and the large pixel 71 and the small pixel 72 have mutually different sensitivities.

Furthermore, the large pixel 71 includes an on-chip lens 81 that condenses light having entered from outside, and the small pixel 72 includes an on-chip lens 82 that condenses light having entered from outside. The on-chip lens 81 and the on-chip lens 82 are arranged on the semiconductor substrate 51, and in this example, a size (lens diameter) of the on-chip lens 81 is larger than that of the on-chip lens 82.

In particular, the on-chip lens 81 of the large pixel 71 has a structure capable of condensing more light than the on-chip lens 82 of the small pixel 72. That is, the on-chip lens 81 can allow a larger amount of light to enter the semiconductor substrate 51 than the on-chip lens 82 due to the structure thereof.

Moreover, the P-well region 61 of the semiconductor substrate 51 is electrically separated into multiple regions by P-type element isolation, that is, a P-type impurity region 83.

For example, as indicated by Arrow Q12, in the unit pixel 62, the P-well region 61 is separated (divided) by the P-type impurity region 83 into a region where the large pixel 71 is formed and a region where the small pixel 72 is formed. Moreover, the region of the large pixel 71 in the P-well region 61 is divided into four regions 91-1 to 91-4 by the P-type impurity region 83.

Note that, a portion indicated by Arrow Q12 indicates a view of the back surface side of the semiconductor substrate 51 viewed from a direction perpendicular to the surface of the semiconductor substrate 51, and the on-chip lens 81 and the on-chip lens 82 are not illustrated here for the sake of description.

As indicated by Arrow Q12, in the small pixel 72, a PD 92 is provided in a region surrounded by the P-type impurity region 83 in the P-well region 61. The on-chip lens 82 condenses light from outside and causes the light to enter the PD 92.

The PD 92 is, for example, a so-called embedded photodiode in which an N-type impurity region is formed inside a P-type impurity region, and functions as a photoelectric conversion unit that receives and photoelectrically converts light entering from the on-chip lens 82.

Similarly to the case of the small pixel 72, also in the large pixel 71, one PD including PDs 93a to 93d is provided in a region surrounded by the P-type impurity region 83 in the P-well region 61. The on-chip lens 81 condenses light from outside and causes the light to enter the PDs 93a to 93d.

In the large pixel 71, the PD 93a is provided in the region 91-1 surrounded by the P-type impurity region 83 in the P-well region 61, and the PD 93b is provided in the region 91-2 surrounded by the P-type impurity region 83 in the P-well region 61.

Similarly, the PD 93c is provided in the region 91-3 surrounded by the P-type impurity region 83 in the P-well region 61, and the PD 93d is provided in the region 91-4 surrounded by the P-type impurity region 83 in the P-well region 61.

The PDs 93a to 93d are, for example, embedded photodiodes in which an N-type impurity region is formed inside a P-type impurity region, and function as photoelectric conversion units that receive and photoelectrically convert light entering from the on-chip lens 81.

Note that, hereinafter, the regions 91-1 to 91-4 are also simply referred to as regions 91 in a case where it is not particularly necessary to distinguish from each other. Furthermore, hereinafter, the PDs 93a to 93d are also simply referred to as PDs 93 in a case where it is not necessary to particularly distinguish from each other. Moreover, hereinafter, one PD including the PDs 93a to 93d is also appropriately referred to as a PD 93.

One PD 93 including the PDs 93a to 93d provided in the large pixel 71 has a larger size than the PD 92 provided in the small pixel 72.

Therefore, for example, when viewed from a direction perpendicular to the surface of the semiconductor substrate 51, a size (area) of a region where the PD 93 is formed, that is, a light receiving surface is larger than a size of a region where the PD 92 is formed, and more light can be received.

Furthermore, it can be said that, in the large pixel 71, the region of one PD 93 is electrically divided (separated) into four PDs 93a to 93d by the P-type impurity region 83.

Therefore, as compared with a case where the PD 93 is not electrically divided, a size (area) of a region of a PN junction portion forming the PD 93, that is, a region of a portion in contact with the P-type impurity region 83 becomes larger. This is also apparent from the fact that, as illustrated in FIG. 2, a total of lengths of outer peripheries of the individual four PDs 93 when viewed from a direction perpendicular to the surface of the semiconductor substrate 51 is longer than a length of an outer periphery in a case where one PD 93 including the PDs 93a to 93d is not divided into four.

Therefore, in the PD 93 of the large pixel 71, a stronger electric field can be obtained, and as a result, a saturation signal amount of the large pixel 71 (PD 93) can be increased.

By doing in this way, in a case where one image with a wide dynamic range is generated using a pixel signal obtained by the large pixel 71 (PD 93) and a pixel signal obtained by the small pixel 72 (PD 92), illuminance serving as the connection point can be made higher illuminance. As a result, the SN characteristic at the connection point can be improved.

Note that, for example, at a time of generating an image, at illuminance lower than the connection point, the pixel value of the pixel is calculated on the basis of a pixel signal for low illuminance or medium illuminance using a signal obtained by the large pixel 71. Whereas, at illuminance higher than the connection point, the pixel value of the pixel is calculated on the basis of a pixel signal for high illuminance using a signal obtained by the small pixel 72. Furthermore, at illuminance serving as the connection point, for example, the pixel value of the pixel is calculated on the basis of a pixel signal for medium illuminance and a pixel signal for high illuminance.

Moreover, as indicated by Arrow Q13, when a surface (front surface) opposite to the back surface side of the semiconductor substrate 51 is viewed from a direction perpendicular to the surface of the semiconductor substrate 51, a plurality of transistors and the like for driving the unit pixel 62 are formed in the unit pixel 62.

For example, in this example, a floating diffusion (FD) 101 is formed in a region surrounded by the PDs 93a to 93d of the large pixel 71 in the semiconductor substrate 51.

The FD 101 is a floating diffusion region, and functions as a charge holding unit that holds (accumulates) charges obtained by photoelectric conversion in the PD 92 or the PD 93.

Furthermore, each of the PDs 93a to 93d and the FD 101 are connected via transfer transistors 102-1 to 102-4 which are transfer gates.

Charges obtained by photoelectric conversion in the PDs 93a to 93d are transferred to the FD 101 via the transfer transistors 102-1 to 102-4, and are accumulated.

Note that, hereinafter, the transfer transistors 102-1 to 102-4 will also be simply referred to as transfer transistors 102 in a case where it is not particularly necessary to distinguish from each other.

Furthermore, here, an example in which the transfer transistor 102 is provided for every divided region of the PD 93 will be described, but one transfer transistor 102 may be provided for a plurality of divided regions of the PD 93.

The unit pixel 62 is provided with the transfer transistor 102, which is for transferring charges to the FD 101, for each of the four PDs 93 constituting the large pixel 71.

Therefore, in the unit pixel 62, capability of transferring charges accumulated in the PD 93 to the FD 101 can be improved as compared with a case where only one transfer transistor 102 is provided. That is, more charges generated by the PD 93 can be read out. As a result, a saturation signal amount of the large pixel 71 can be substantially increased.

Furthermore, the PD 92 of the small pixel 72 is also connected to the FD 101 via a transfer transistor 103 and a transfer transistor 104. Therefore, it is also possible to transfer charges obtained by photoelectric conversion in the PD 92 to the FD 101 via the transfer transistor 104 and the transfer transistor 103, and accumulate.

Furthermore, a reset transistor 105 is also connected to the transfer transistor 103, and it is possible to discharge charges accumulated in the FD 101 and the like and perform resetting, by bringing the reset transistor 105 into an ON state (bringing into a conductive state).

Furthermore, the FD 101 is connected to a gate of an amplification transistor 106. The amplification transistor 106 outputs a signal corresponding to a potential of the FD 101.

That is, the amplification transistor 106 constitutes a source follower circuit with a constant current source connected via the vertical signal line 27, and a signal indicating a level corresponding to charges accumulated in the FD 101 is output from the amplification transistor 106 to the column processing unit 23 via a selection transistor 107 and the vertical signal line 27.

Furthermore, a P-type contact 108 connected to a ground is also formed in a portion between the PD 93b and the PD 93d in the semiconductor substrate 51.

In the pixel array unit 21, a plurality of the unit pixels 62 having the above-described configuration is formed. According to the CMOS image sensor 11 including such a pixel array unit 21, it is possible to increase a saturation signal amount of the large pixel 71 and improve an SN characteristic at the connection point.

Note that, although an example in which the semiconductor substrate 51 is the P-type semiconductor substrate has been described above, the semiconductor substrate 51 may be an N-type semiconductor substrate. In such a case, the semiconductor substrate 51 is electrically separated into multiple regions by N-type element isolation corresponding to the P-type impurity region 83, that is, an N-type impurity region. Therefore, for example, the region of the large pixel 71 is divided into the four regions 91-1 to 91-4 (PDs 93a to 93d) by the N-type impurity region.

### Second Embodiment

<Another Configuration Example of Unit Pixel>

A configuration of the unit pixel 62 is not limited to the configuration illustrated in FIG. 2, and may have any configuration as long as the large pixel 71 and the small pixel 72 are included and the region of the large pixel 71 is divided into multiple regions.

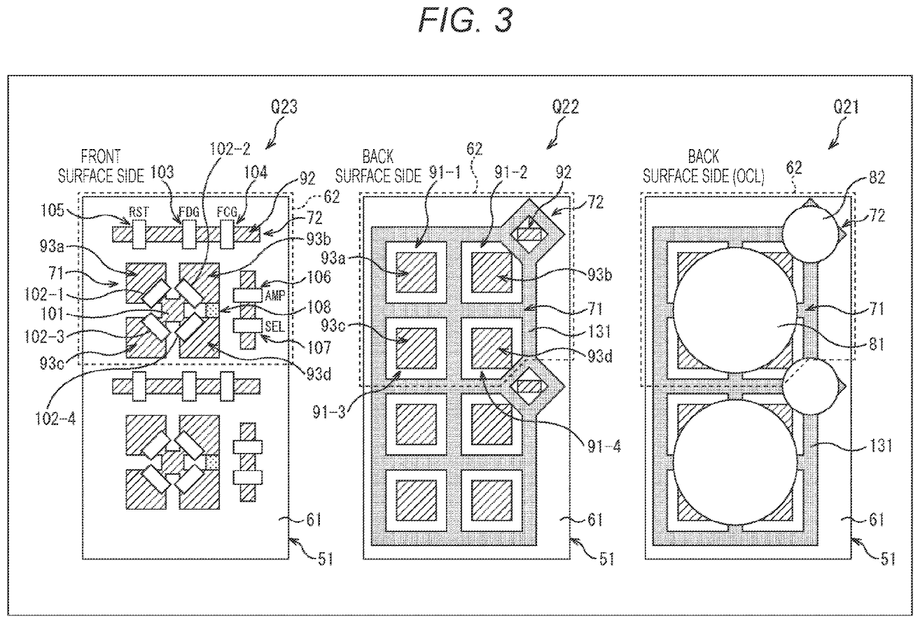

Hereinafter, other configuration examples of the unit pixel 62 will be described with reference to FIGS. 3 to 8. Note that, in FIGS. 3 to 8, portions corresponding to those in the case of FIG. 2 are denoted by the same reference numerals, and a description thereof will be omitted as appropriate. Furthermore, in FIGS. 3 to 8, the same reference numerals are assigned to portions corresponding to each other, and a description thereof will be omitted as appropriate.

The example illustrated in FIG. 3 basically has the same configuration as the case in FIG. 2. However, in the example illustrated in FIG. 3, a P-well region 61 of a semiconductor substrate 51 is electrically separated into multiple regions not by a P-type impurity region 83 but by an insulator 131.

That is, the configuration of the unit pixel 62 illustrated in FIG. 3 is different from the configuration of the unit pixel 62 illustrated in FIG. 2 only in that the insulator 131 is provided instead of the P-type impurity region 83, and other points have the same configurations as those of the unit pixel 62 illustrated in FIG. 2.

In FIG. 3, a portion indicated by Arrow Q21 and a portion indicated by Arrow Q22 indicate views of a part of a back surface side of the semiconductor substrate 51, as viewed from a direction perpendicular to the surface of the semiconductor substrate 51. However, an on-chip lens 81 and an on-chip lens 82 are not drawn in the portion indicated by Arrow Q22.

As indicated by Arrow Q22, in the unit pixel 62, the P-well region 61 is separated (divided) by the insulator 131 into a region where a large pixel 71 is formed and a region where a small pixel 72 is formed.

Moreover, the region of the large pixel 71 in the P-well region 61 is divided into four regions 91-1 to 91-4 by the insulator 131, and PDs 93a to 93d are formed in the regions 91-1 to 91-4.

The insulator 131 is made by, for example, a rear deep trench isolation (RDTI), a front full trench isolation (FFTI), or the like.

Here, the RDTI is a trench formed by forming a groove from the back surface side of the semiconductor substrate 51 to a predetermined depth and embedding an insulator or the like in the groove portion. Furthermore, the FFTI is a trench formed by forming a hole (groove) penetrating from a front surface side to the back surface of the semiconductor substrate 51 and embedding an insulator or the like in the through-hole portion.

In a case where such an insulator 131 is formed, a thin P-type semiconductor region is formed on the front surface of the insulator 131. Therefore, also by electrically dividing the region of the PD 93 into the four PDs 93a to 93d by the insulator 131, similarly to the case of division by the P-type impurity region 83, a region of a PN junction portion forming the PD 93 can be enlarged. Therefore, a stronger electric field can be obtained in the PD 93 of the large pixel 71, and a saturation signal amount of the large pixel 71 (PD 93) can be increased.

Furthermore, as indicated by Arrow Q23, when the front surface side of the semiconductor substrate 51 is viewed from a direction perpendicular to the surface of the semiconductor substrate 51, the PD 93, a PD 92, and an FD 101 to a P-type contact 108 are formed in the unit pixel 62 in the same arrangement as in the example of FIG. 2.

### Third Embodiment

<Another Configuration Example of Unit Pixel>

In the example of FIG. 3, an example has been described in which one PD 93 including the PDs 93a to 93d is formed by forming the N-type impurity region for every region 91 in the large pixel 71 divided by the insulator 131.

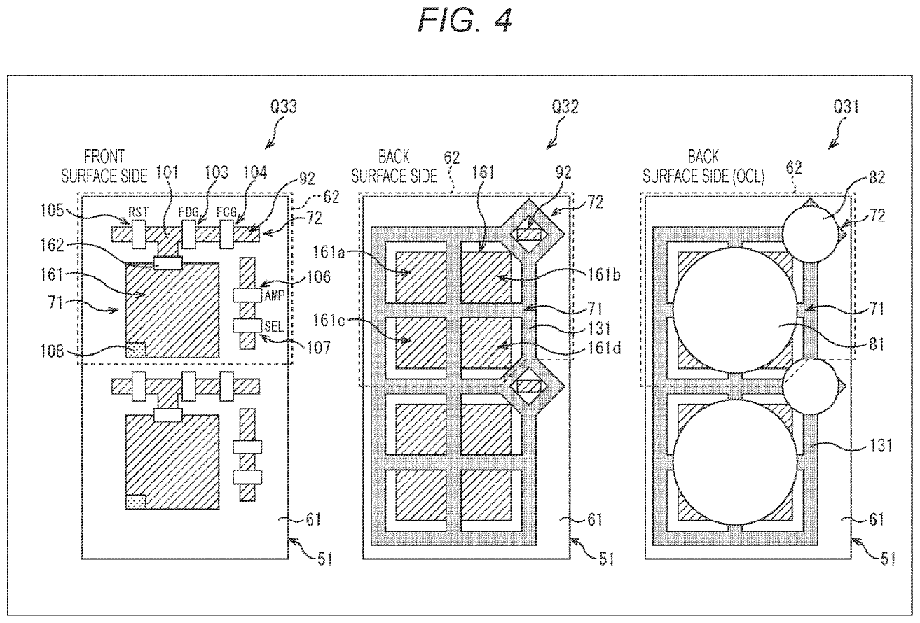

However, for example, as illustrated in FIG. 4, one PD 161 may be formed by forming an N-type impurity region inside a P-type impurity region, and the PD 161 may be divided by an insulator 131.

In FIG. 4, a portion indicated by Arrow Q31 and a portion indicated by Arrow Q32 indicate views of a part of a back surface side of a semiconductor substrate 51, as viewed from a direction perpendicular to the surface of the semiconductor substrate 51. However, an on-chip lens 81 and an on-chip lens 82 are not drawn in the portion indicated by Arrow Q32.

As indicated by Arrow Q32, in a unit pixel 62, a P-well region 61 is separated (divided) by the insulator 131 into a region where a large pixel 71 is formed and a region where a small pixel 72 is formed. For example, in this example, the insulator 131 is RDTI or the like.

In the large pixel 71, one PD 161 is formed, and the PD 161 is electrically separated (divided) into four PDs 161a to 161d by the insulator 131. Also with such a configuration, similarly to the example of FIG. 3, a region of a PN junction portion forming the PD 161 can be enlarged, and a saturation signal amount can be increased.

Furthermore, as indicated by Arrow Q33, when a front surface side of the semiconductor substrate 51 is viewed from a direction perpendicular to the surface of the semiconductor substrate 51, a transistor and the like are arranged in the unit pixel 62 in an arrangement different from that in the example of FIG. 3.

In this example, the PD 161, a PD 92, a transfer transistor 162, an FD 101, and a transfer transistor 103 to a P-type contact 108 are formed in the unit pixel 62.

In particular, in the example of FIG. 4, unlike the case in FIG. 3, charges generated by photoelectric conversion in the PD 161 are transferred to the FD 101 by one transfer transistor 162. That is, charges accumulated in each of the PDs 161a to 161d are transferred to the FD 101 by the same transfer transistor 162.

Furthermore, the transfer transistor 103 and the amplification transistor 106 are connected to the FD 101, and an arrangement of the transfer transistor 103 to the selection transistor 107 is the same as that in the example in FIG. 3. Moreover, the P-type contact 108 is arranged at a lower left position of the PD 161 in the figure when viewed from a direction perpendicular to the surface of the semiconductor substrate 51.

### Fourth Embodiment

<Another Configuration Example of Unit Pixel>

Furthermore, in the examples illustrated in FIGS. 2 to 4, an example has been described in which the pixel transistor such as the transfer transistor 162 for driving the unit pixel 62 is arranged in a region different from the PD when viewed from a direction perpendicular to the surface of the semiconductor substrate 51. However, without limiting to this, the pixel transistor may be arranged in a region immediately below the PD.

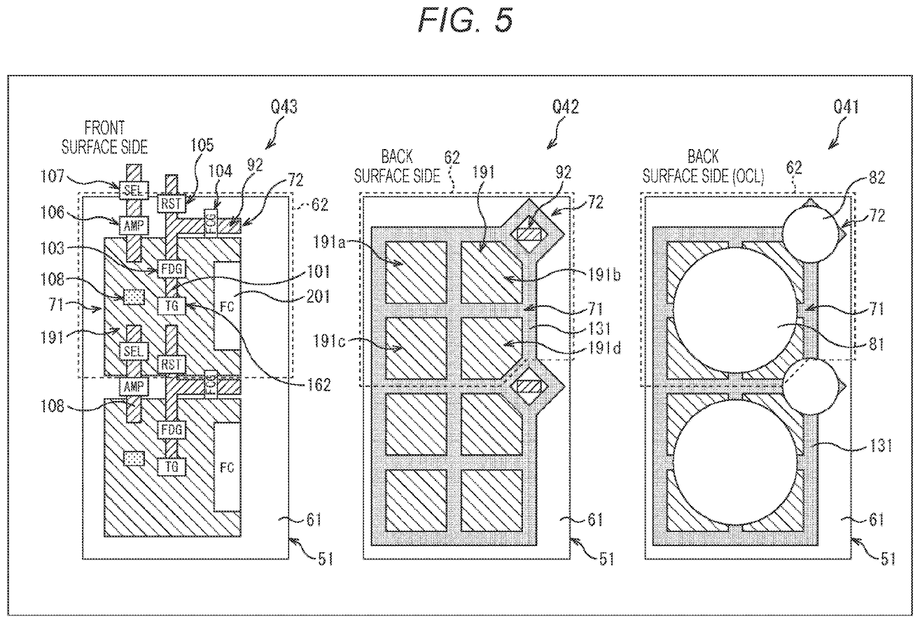

In such a case, the unit pixel 62 is configured as illustrated in FIG. 5, for example.

In FIG. 5, a portion indicated by Arrow Q41 and a portion indicated by Arrow Q42 indicate views of a part of a back surface side of a semiconductor substrate 51, as viewed from a direction perpendicular to the surface of the semiconductor substrate 51. However, an on-chip lens 81 and an on-chip lens 82 are not drawn in the portion indicated by Arrow Q42.

As indicated by Arrow Q42, in a unit pixel 62, a P-well region 61 is separated (divided) by an insulator 131 into a region where a large pixel 71 is formed and a region where a small pixel 72 is formed, similarly to the case in FIG. 4.

In the large pixel 71, one PD 191 similar to the PD 161 illustrated in FIG. 4 is formed, and the PD 191 is electrically separated (divided) into four PDs 191a to 191d by the insulator 131. In particular, in this example, since the pixel transistor is formed immediately below the PD 191, the PD 191 is larger than the PD 161.

Also with such a configuration, similarly to the example of FIG. 4, a region of a PN junction portion forming the PD 191 can be enlarged, and a saturation signal amount can be increased.

Furthermore, as indicated by Arrow Q43, when a front surface side of the semiconductor substrate 51 is viewed from a direction perpendicular to the surface of the semiconductor substrate 51, a transistor and the like are arranged in the unit pixel 62 in an arrangement different from that in the example of FIG. 4.

That is, when viewed from a direction perpendicular to the surface of the semiconductor substrate 51, a transfer transistor 162, an FD 101, a transfer transistor 103, a capacitor 201, and a P-type contact 108, and a reset transistor and a selection transistor of an adjacent unit pixel are arranged at positions overlapping with a region of the PD 191.

Furthermore, in the unit pixel 62, a transfer transistor 104 to a selection transistor 107, and a PD 92 are arranged at positions different from (positions not overlapping) the region of the PD 191, when viewed from a direction perpendicular to the surface of the semiconductor substrate 51.

For example, the capacitor 201 is a floating capacitor (FC), and is formed in a layer (wiring layer) same as the transfer transistor 162. The capacitor 201 is connected between the PD 92 and the transfer transistor 104, and holds (accumulates) charges generated by photoelectric conversion in the PD 92. Therefore, by providing the capacitor 201, a saturation signal amount of the small pixel 72 (PD 92) can be further increased.

Furthermore, in the example of FIG. 5, similarly to the case of FIG. 4, charges generated by photoelectric conversion in the PD 191 are transferred to the FD 101 by one transfer transistor 162. That is, charges accumulated in each of the PDs 191a to 191d are transferred to the FD 101 by the same transfer transistor 162.

### Fifth Embodiment

<Another Configuration Example of Unit Pixel>

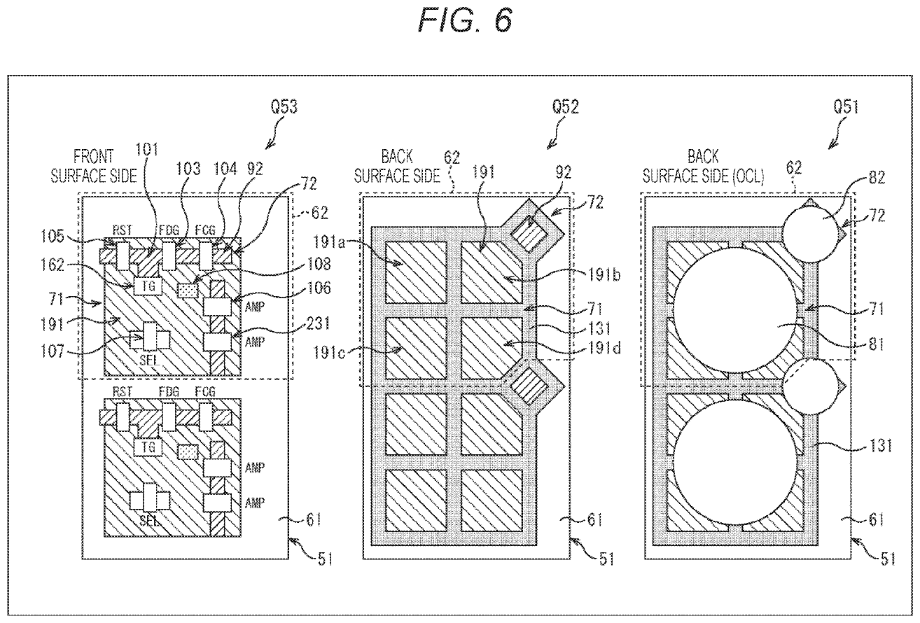

Moreover, an example in which one amplification transistor 106 is provided in the unit pixel 62 has been described above. However, for example, as illustrated in FIG. 6, multiple amplification transistors connected in parallel may be arranged in the unit pixel 62.

In FIG. 6, a portion indicated by Arrow Q51 and a portion indicated by Arrow Q52 indicate views of a part of a back surface side of a semiconductor substrate 51, as viewed from a direction perpendicular to the surface of the semiconductor substrate 51. However, an on-chip lens 81 and an on-chip lens 82 are not drawn in the portion indicated by Arrow Q52.

In this example, as indicated by Arrow Q52, a P-well region 61 is separated by an insulator 131 into a region where a large pixel 71 is formed and a region where a small pixel 72 is formed, similarly to the case in FIG. 5. Furthermore, one PD 191 is formed in the large pixel 71, and the PD 191 is divided into four PDs 191a to 191d by the insulator 131.

Moreover, as indicated by Arrow Q53, a pixel transistor or the like is arranged at a position overlapping with a region of the PD 191, when a front surface side of a semiconductor substrate 51 is viewed from a direction perpendicular to the surface of the semiconductor substrate 51. That is, a transfer transistor 162, an FD 101, a transfer transistor 103 to a P-type contact 108, and an amplification transistor 231 are formed immediately below the PD 191.

Also in this example, similarly to the case in FIG. 5, charges accumulated in the PD 191, that is, in each of the PDs 191a to 191d, are transferred to the FD 101 by one transfer transistor 162.

Furthermore, the amplification transistor 231 is provided between the amplification transistor 106 and the selection transistor 107. That is, the amplification transistor 106 and the amplification transistor 231 are connected in parallel between the FD 101 and the selection transistor 107.

Therefore, a signal indicating a level corresponding to charges accumulated (held) in the FD 101 is output from the amplification transistor 106 and the amplification transistor 231 to a vertical signal line 27 via the selection transistor 107.

As described above, by arranging the two amplification transistors 106 and 231 in parallel, it is possible to substantially increase a length (gate length W) of a gate of the amplification transistor in a lateral direction in the figure. That is, the gate length W can be increased as compared with a case where one amplification transistor is provided.

As a result, a speed for reading a signal from the unit pixel 62 (FD 101) can be further increased, and noise included in the read signal can be reduced.

### Sixth Embodiment

<Another Configuration Example of Unit Pixel>

Furthermore, for example, in the configuration illustrated in FIG. 3, a capacitor may be further directly connected to the small pixel 72.

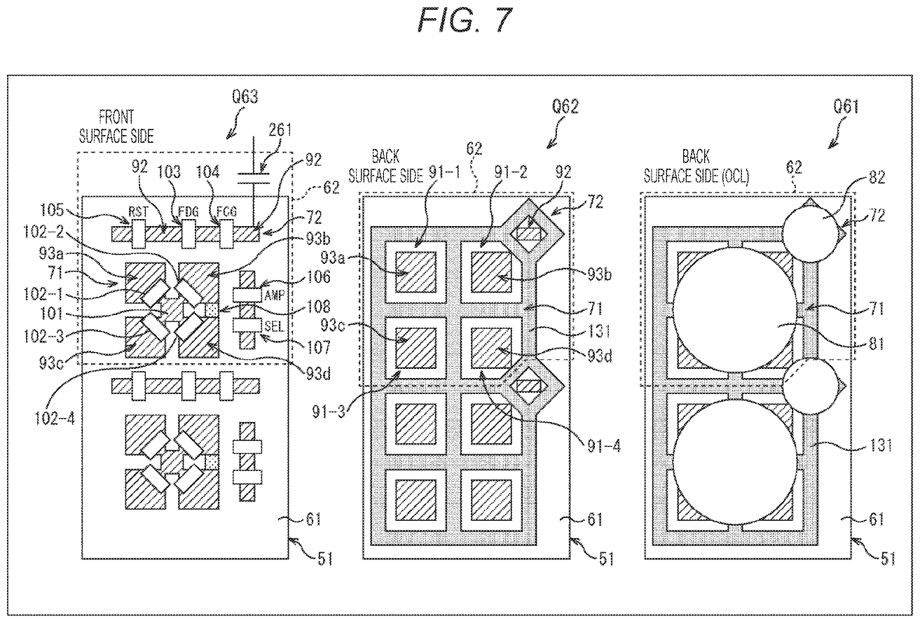

In such a case, the unit pixel 62 is configured as illustrated in FIG. 7, for example.

In FIG. 7, a portion indicated by Arrow Q61 and a portion indicated by Arrow Q62 indicate views of a part of a back surface side of a semiconductor substrate 51, as viewed from a direction perpendicular to the surface of the semiconductor substrate 51. However, an on-chip lens 81 and an on-chip lens 82 are not drawn in the portion indicated by Arrow Q62.

In this example, as indicated by Arrow Q62, a P-well region 61 is separated by an insulator 131 into a region where a large pixel 71 is formed and a region where a small pixel 72 is formed, similarly to the case in FIG. 3. Furthermore, the region of the large pixel 71 is divided into four regions 91-1 to 91-4 by the insulator 131, and PDs 93a to 93d are formed in the regions 91-1 to 91-4.

As indicated by Arrow Q63, when a front surface side of the semiconductor substrate 51 is viewed from a direction perpendicular to the surface of the semiconductor substrate 51, the PD 93, a PD 92, and an FD 101 to a P-type contact 108 are formed in the unit pixel 62 in the same arrangement as in the example of FIG. 3.

Furthermore, in the example of FIG. 7, a capacitor 261 is directly connected to the PD 92, and charges generated by photoelectric conversion in the PD 92 are accumulated (held) not only in the PD 92 but also in the capacitor 261. As a result, a saturation signal amount of the small pixel 72 (PD 92) can be further increased.

The capacitor 261 is made by, for example, a metal insulator metal (MIM), a metal oxide semiconductor (MOS) capacitor (MOSCAP), a trench, and the like.

For example, in a case where the capacitor 261 is made by an MIM, that is, by a capacitor having an MIM structure, the capacitor 261 is formed in a wiring layer (not illustrated) constituting the semiconductor substrate 51, so that a degree of freedom in a layout of the capacitor 261 can be further increased.

### Seventh Embodiment

<Another Configuration Example of Unit Pixel>

Furthermore, for example, in the configuration illustrated in FIG. 7, a capacitor may be further connected to the FD 101 of the large pixel 71.

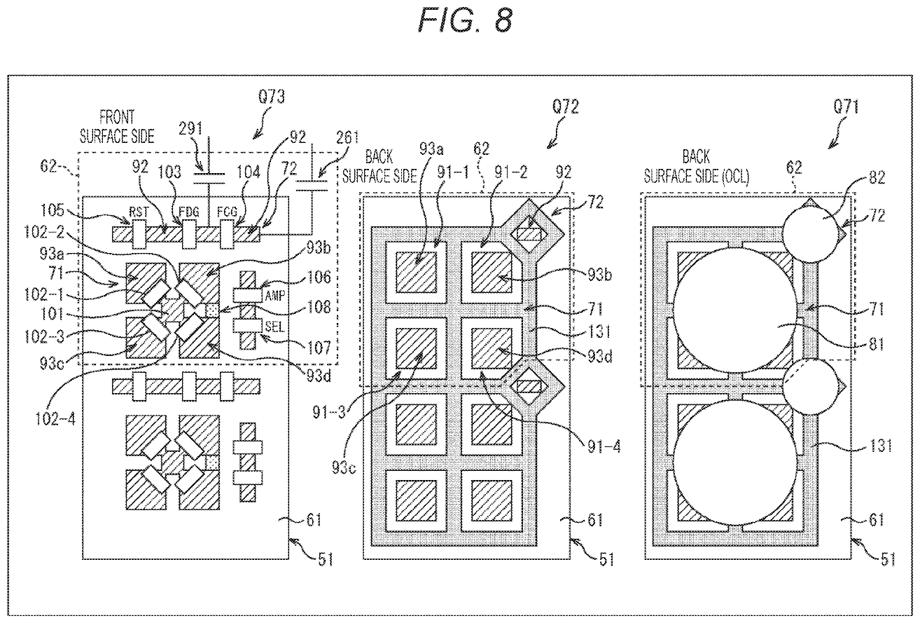

In such a case, the unit pixel 62 is configured as illustrated in FIG. 8, for example.

In FIG. 8, a portion indicated by Arrow Q71 and a portion indicated by Arrow Q72 indicate views of a part of a back surface side of a semiconductor substrate 51, as viewed from a direction perpendicular to the surface of the semiconductor substrate 51. However, an on-chip lens 81 and an on-chip lens 82 are not drawn in the portion indicated by Arrow Q72.

In this example, as indicated by Arrow Q72, a P-well region 61 is separated by an insulator 131 into a region where a large pixel 71 is formed and a region where a small pixel 72 is formed, similarly to the case in FIG. 7. Furthermore, the region of the large pixel 71 is divided into four regions 91-1 to 91-4 by the insulator 131, and PDs 93a to 93d are formed in the regions 91-1 to 91-4.

As indicated by Arrow Q73, when a front surface side of the semiconductor substrate 51 is viewed from a direction perpendicular to the surface of the semiconductor substrate 51, the PD 93, a PD 92, and an FD 101 to a P-type contacts 108 are formed in the unit pixel 62 in the same arrangement as in the example of FIG. 8.

Moreover, in the example of FIG. 8, a capacitor 261 is connected to the PD 92, and a capacitor 291 is also connected to the FD 101.

More specifically, the capacitor 291 is connected between the transfer transistor 103 and the transfer transistor 104. In other words, the capacitor 291 is connected to the FD 101 via the transfer transistor 103.

Therefore, for example, when the transfer transistor 103 is brought into an ON state (conductive state), a capacitance (saturation signal amount) of the FD 101 can be further increased by an amount of the capacitor 291 as compared with the case in the example illustrated in FIG. 7. That is, by providing the capacitor 291 having an appropriate capacitance, conversion efficiency from a charge to a voltage signal can be adjusted.

For example, the capacitor 291 is made by an MIM and is formed in a wiring layer (not illustrated) constituting the semiconductor substrate 51. Therefore, similarly to the case of the capacitor 261, a degree of freedom of a layout of the capacitor 291 can be further increased.

<Circuit Configuration Example of Unit Pixel>

Next, a circuit configuration of the unit pixel 62 described above will be described.

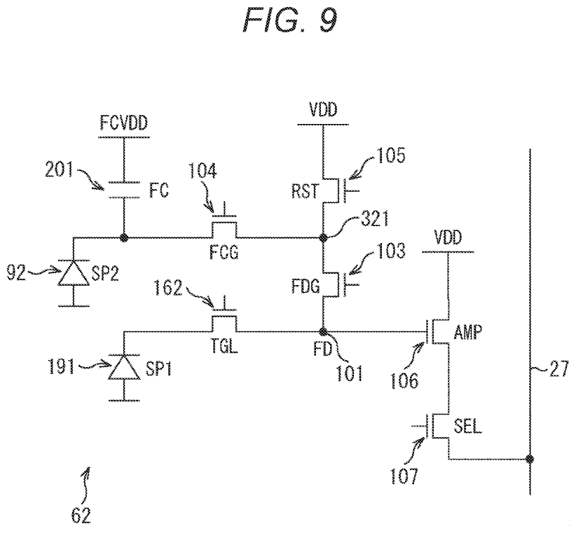

For example, in a case where the unit pixel 62 has the configuration illustrated in FIG. 5, the circuit configuration of the unit pixel 62 is as illustrated in FIG. 9. Note that, in FIG. 9, portions corresponding to those in the case of FIG. 5 are denoted by the same reference numerals, and a description thereof will be omitted as appropriate.

In the example illustrated in FIG. 9, the unit pixel 62 includes the PD 191, the transfer transistor 162, the FD 101, the transfer transistor 103, the transfer transistor 104, the PD 92, the capacitor 201, the reset transistor 105, the amplification transistor 106, and the selection transistor 107.

In the unit pixel 62, the transfer transistor 162 is provided between the PD 191 and the FD 101. Furthermore, the FD 101 is connected to a node 321 via the transfer transistor 103. When the transfer transistor 103 is brought into an ON state, the FD 101 and the node 321 are electrically connected, and the node 321 functions as an FD. That is, a capacity of the FD 101 substantially increases by an amount of the node 321.

To the node 321, the transfer transistor 104 and the reset transistor 105 are also connected.

To the transfer transistor 104, the PD 92 and the capacitor 201 are also connected. In particular, one end of the capacitor 201 is connected to the PD 92 and the transfer transistor 104, and another end is connected to a power supply FCVDD of a predetermined voltage.

Charges obtained by photoelectric conversion in the PD 92 are accumulated in the PD 92 and the capacitor 201. When the transfer transistor 104 is brought into an ON state, the charges are transferred to the node 321 via the transfer transistor 104.

Furthermore, the reset transistor 105 is connected to a power supply VDD. When the reset transistor 105 and the transfer transistor 103 are brought into an ON state, the charges accumulated in the FD 101 and the node 321 are discharged to the power supply VDD.

Moreover, the FD 101 is connected to a gate of the amplification transistor 106, and the amplification transistor 106 is connected to the vertical signal line 27 via the selection transistor 107.

Note that, even in a case where the unit pixel 62 has the configuration illustrated in FIG. 4 or 6, the unit pixel 62 has a circuit configuration similar to that of the example illustrated in FIG. 9.

However, for example, in the case of the configuration illustrated in FIG. 4, the unit pixel 62 is not provided with the capacitor 201. Furthermore, in the case of the configuration illustrated in FIG. 6, the capacitor 201 is not provided in the unit pixel 62, and the amplification transistor 231 is provided between the amplification transistor 106 and the selection transistor 107.

<Another Circuit Configuration Example of Unit Pixel>

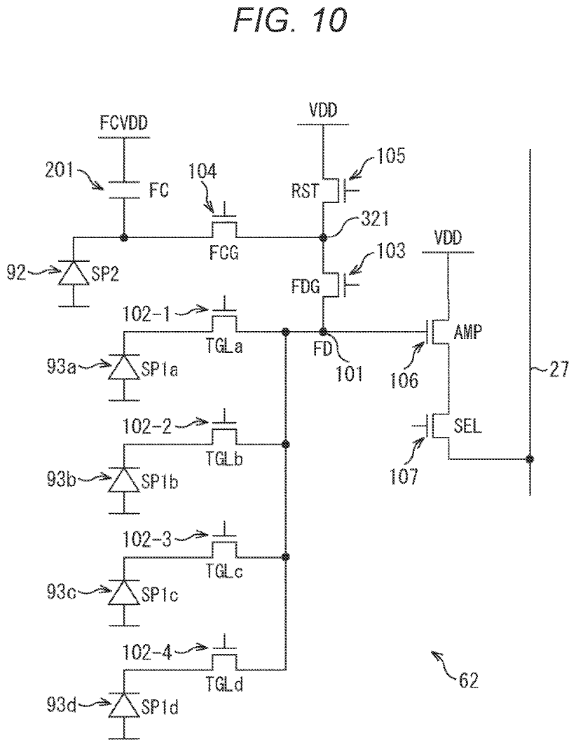

In addition, the circuit configuration of the unit pixel 62 may be configured as illustrated in FIG. 10, for example. Note that, in FIG. 10, portions corresponding to those in the case of FIG. 2 or 9 are denoted by the same reference numerals, and a description thereof will be omitted as appropriate.

The configuration of the unit pixel 62 illustrated in FIG. 10 is different from the unit pixel 62 in FIG. 9 in that the PDs 93a to 93d and the transfer transistors 102-1 to 102-4 are provided instead of the PD 191 and the transfer transistor 162, and other points have the same configurations as those of the unit pixel 62 illustrated in FIG. 9.

That is, in the example of FIG. 10, each of the PDs 93a to 93d is connected to the FD 101 via each of the transfer transistors 102-1 to 102-4. Therefore, charges obtained by photoelectric conversion in each of the four PDs 93 are transferred to the FD 101 via the transfer transistor 102.

At this time, by supplying control signals TGLa to TGLd to the individual transfer transistors 102 via the pixel drive line 26, the vertical drive unit 22 brings these transfer transistors 102 into an ON state.

Note that the vertical drive unit 22 and each of the transfer transistors 102-1 to 102-4 can be connected by the same one pixel drive line 26, and the same control signal can be supplied as the control signals TGLa to TGLd.

In such a case, since the four transfer transistors 102 each are simultaneously controlled and perform the same operation, charges accumulated in the PDs 93a to 93d are simultaneously transferred to the FD 101.

Furthermore, the vertical drive unit 22 and each of the transfer transistors 102-1 to 102-4 may be connected by mutually different pixel drive lines 26, and mutually different control signals may be supplied as the control signals TGLa to TGLd.

In such a case, since the four transfer transistors 102 are individually (independently) controlled, charges accumulated in each of the PDs 93a to 93d are transferred to the FD 101 at any timing. That is, the vertical drive unit 22 can transfer charges accumulated in each PD 93 to the FD 101 at the same time, or can individually transfer the charges to the FD 101 at mutually different timings.

For example, if the charges accumulated in each PD 93 are individually transferred to the FD 101 and signals corresponding to the charges are individually read, an amount of information regarding incident light obtained in the unit pixel 62 increases. Therefore, a resolution of an image obtained by the CMOS image sensor 11 can be increased.

The circuit configuration of the unit pixel 62 illustrated in FIG. 10 corresponds to, for example, the configuration illustrated in FIGS. 2, 3, 7, and 8 described above.

For example, the configuration of the unit pixel 62 illustrated in FIG. 2 or 3 is a configuration obtained by removing the capacitor 201 from the configuration of the unit pixel 62 illustrated in FIG. 10, while the configuration of the unit pixel 62 illustrated in FIG. 7 is a configuration in which the capacitor 201 in the unit pixel 62 illustrated in FIG. 10 is replaced with the capacitor 261.

Furthermore, for example, the configuration of the unit pixel 62 illustrated in FIG. 8 is a configuration in which the capacitor 201 in the unit pixel 62 illustrated in FIG. 10 is replaced with the capacitor 261, and the capacitor 291 is provided at the node 321.

<Drive Example of Unit Pixel>

Next, a drive example of the unit pixel 62 described above, that is, an operation of the CMOS image sensor 11 will be described. Note that, here, a description will be given assuming that a circuit configuration of the unit pixel 62 is the configuration illustrated in FIG. 9.

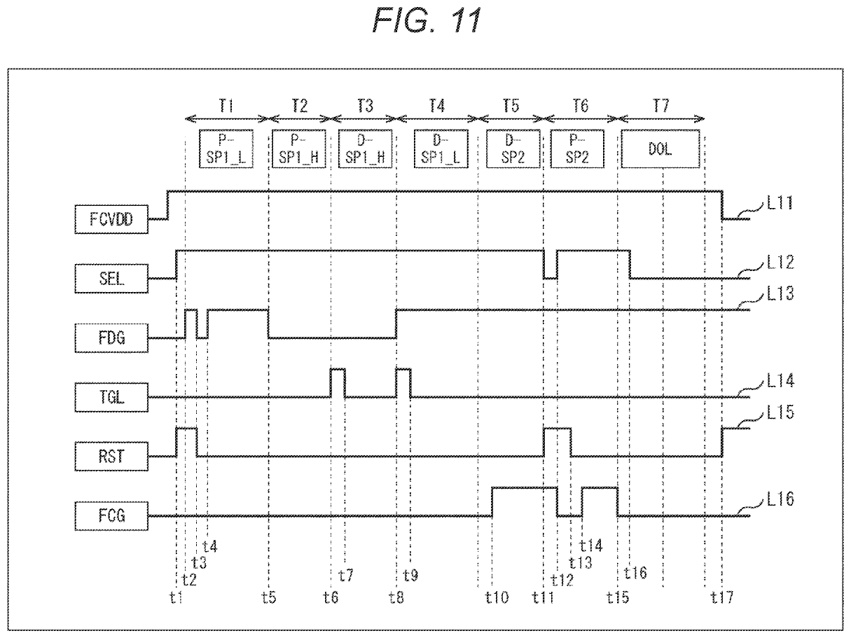

FIG. 11 illustrates a drive example of the unit pixel 62 in a 1H period (one horizontal period) in the pixel array unit 21, and a lateral direction indicates a time direction in the figure.

In FIG. 11, a polygonal line L11 indicates a voltage of the power supply FCVDD supplied to the capacitor 201 and the like.

Furthermore, a polygonal line L12 indicates a control signal SEL supplied from the vertical drive unit 22 to the selection transistor 107 via the pixel drive line 26, and a polygonal line L13 indicates a control signal FDG supplied from the vertical drive unit 22 to the transfer transistor 103 via the pixel drive line 26.

A polygonal line L14 indicates a control signal TGL supplied from the vertical drive unit 22 to the transfer transistor 162 via the pixel drive line 26, and a polygonal line L15 indicates a control signal RST supplied from the vertical drive unit 22 to the reset transistor 105 via the pixel drive line 26.

Moreover, a polygonal line L16 indicates a control signal FCG supplied from the vertical drive unit 22 to the transfer transistor 104 via the pixel drive line 26.

Note that, for the polygonal lines L12 to L16, a pixel transistor such as the selection transistor 107 corresponding to the polygonal line is brought into an ON state (conductive state) in a period in which the polygonal line is convex upward in the figure, and the pixel transistor corresponding to the polygonal line is brought into an OFF state (non-conductive state) in a period in which the polygonal line is convex downward in the figure.

For example, in FIG. 11, a first period T1 is a readout period of a P-phase for obtaining a pixel signal corresponding to medium illuminance that is illuminance of a medium level, that is, a reset level.

Subsequent periods T2 and T3 are readout periods of a P-phase and a D-phase for obtaining a pixel signal corresponding to low illuminance that is the lowest illuminance, that is, a reset level and a signal level. Furthermore, a period T4 is a readout period of a D-phase for obtaining a pixel signal corresponding to medium illuminance, that is, a signal level.

Moreover, periods T5 and T6 are readout periods of a D-phase and a P-phase for obtaining a pixel signal corresponding to high illuminance that is the highest illuminance, that is, a signal level and a reset level, and a period T7 is a period for digital overlap (DOL).

For example, at time t1 before the period T1, the vertical drive unit 22 brings the selection transistor 107 and the reset transistor 105 into an ON state. At this time, the transfer transistor 103, the transfer transistor 162, and the transfer transistor 104 are in an OFF state.

At the following time t2, the vertical drive unit 22 electrically connects the FD 101 and the node 321 by bringing the transfer transistor 103 into an ON state.

As a result, charges accumulated in the FD 101 and the node 321 are discharged, and the FD 101 and the node 321 are reset.

A state in which the FD 101 and the node 321 are connected is a low conversion efficiency state in which conversion efficiency from a charge into a voltage signal is low as compared with a state in which the FD 101 and the node 321 are not connected. Reading of a pixel signal corresponding to the medium illuminance is performed in the low conversion efficiency state.

At time t3, the vertical drive unit 22 brings the transfer transistor 103 and the reset transistor 105 into an OFF state, and thereafter, at time t4, the vertical drive unit 22 brings the transfer transistor 103 into an ON state again.

As a result, in the low conversion efficiency state in which the FD 101 and the node 321 are connected, a voltage signal corresponding to charges held in the FD 101 and the node 321 is supplied from the amplification transistor 106 to the column processing unit 23 via the selection transistor 107 and the vertical signal line 27.

The column processing unit 23 performs signal processing such as AD conversion processing on the signal supplied from the amplification transistor 106 in this manner, to obtain a reset level corresponding to the medium illuminance.

Furthermore, at time t5, the vertical drive unit 22 brings the transfer transistor 103 into an OFF state.

As a result, the FD 101 and the node 321 are electrically separated, and a high conversion efficiency state in which conversion efficiency is higher than the low conversion efficiency state is obtained. The reading of the pixel signal corresponding to the low illuminance is performed in the high conversion efficiency state.

In this state, a voltage signal corresponding to charges held in the FD 101 is supplied from the amplification transistor 106 to the column processing unit 23 via the selection transistor 107 and the vertical signal line 27. The column processing unit 23 performs signal processing such as AD conversion processing on the signal supplied from the amplification transistor 106 in this manner, to obtain a reset level corresponding to the low illuminance.

At time t6, the vertical drive unit 22 brings the transfer transistor 162 into an ON state.

The PD 191 performs photoelectric conversion, and charges obtained as a result thereof are accumulated. When the transfer transistor 162 is brought into an ON state, charges accumulated in the PD 191 are transferred to the FD 101 via the transfer transistor 162 and held.

In this case, since the FD 101 and the node 321 are electrically separated, that is, are not connected, the conversion efficiency is in the high conversion efficiency state.

At time t7, the vertical drive unit 22 brings the transfer transistor 162 into an OFF state, and ends the transfer of the charges from the PD 191 to the FD 101.

In this state, a voltage signal corresponding to charges held in the FD 101 is supplied from the amplification transistor 106 to the column processing unit 23 via the selection transistor 107 and the vertical signal line 27. The column processing unit 23 performs signal processing such as AD conversion processing on the signal supplied from the amplification transistor 106 in this manner, to obtain a signal level corresponding to the low illuminance.

Furthermore, the column processing unit 23 obtains a pixel signal corresponding to the low illuminance by obtaining a difference between the signal level and the reset level corresponding to the low illuminance, and supplies the pixel signal to the signal processing unit 28. Note that the difference between the signal level and the reset level may be calculated by the signal processing unit 28.

At time t8, the vertical drive unit 22 brings the transfer transistor 162 into an ON state to further transfer charges from the PD 191 to the FD 101, and brings the transfer transistor 103 into an ON state to obtain the low conversion efficiency state again. In this case, the charges transferred from the PD 191 are accumulated in the FD 101 and the node 321.

At time t9, the vertical drive unit 22 brings the transfer transistor 162 into an OFF state, and ends the transfer of the charges from the PD 191 to the FD 101.

In this state, a voltage signal corresponding to charges held in the FD 101 and the node 321 is supplied from the amplification transistor 106 to the column processing unit 23 via the selection transistor 107 and the vertical signal line 27.

The column processing unit 23 performs signal processing such as AD conversion processing on the signal supplied from the amplification transistor 106 in this manner, to obtain a signal level corresponding to the medium illuminance. Furthermore, the column processing unit 23 obtains a pixel signal corresponding to the medium illuminance by obtaining a difference between the signal level and the reset level corresponding to the medium illuminance, and supplies the pixel signal to the signal processing unit 28.

Driving for obtaining the pixel signal corresponding to the low illuminance and the medium illuminance as described above is CDS driving.

Subsequently, at time t10, the vertical drive unit 22 brings the transfer transistor 104 into an ON state.

The PD 92 performs photoelectric conversion, and charges obtained as a result thereof are accumulated in the PD 92 and the capacitor 201. When the transfer transistor 104 is brought into an ON state, the charges accumulated in the PD 92 and the capacitor 201 are transferred to the node 321 (FD 101) via the transfer transistor 104 and held.

In this case, the PD 92, the capacitor 201, the FD 101, and the node 321 are electrically connected, and the conversion efficiency is further lower than that in the low conversion efficiency state. Reading of a pixel signal corresponding to the high illuminance is performed in such a state in which the conversion efficiency is lower than the low conversion efficiency.

That is, in such a state, a voltage signal corresponding to charges held in the FD 101, the node 321, and the capacitor 201 is supplied from the amplification transistor 106 to the column processing unit 23 via the selection transistor 107 and the vertical signal line 27.

The column processing unit 23 performs signal processing such as AD conversion processing on the signal supplied from the amplification transistor 106 in this manner, to obtain a signal level corresponding to the high illuminance.

At time t11, the vertical drive unit 22 brings the selection transistor 107 into an OFF state to temporarily bring the unit pixel 62 into a non-selected state, that is, a state in which no signal is output to the vertical signal line 27, and brings the reset transistor 105 into an ON state to perform resetting.

In this case, charges accumulated in the PD 92, the capacitor 201, the FD 101, and the node 321 are discharged, and the PD 92, the capacitor 201, the FD 101, and the node 321 are reset.

At time t12, the vertical drive unit 22 brings the selection transistor 107 into an ON state again to bring the unit pixel 62 into a selected state, and brings the transfer transistor 104 into an OFF state to electrically disconnect the PD 92 and the capacitor 201 from the node 321.

Then, at time t13, the vertical drive unit 22 brings the reset transistor 105 into an OFF state and ends the resetting.

At time t14, the vertical drive unit 22 brings the transfer transistor 104 into an ON state to obtain a state in which the PD 92, the capacitor 201, the FD 101, and the node 321 are electrically connected.

In such a state, a voltage signal corresponding to charges held in the FD 101, the node 321, and the capacitor 201 is supplied from the amplification transistor 106 to the column processing unit 23 via the selection transistor 107 and the vertical signal line 27.

The column processing unit 23 performs signal processing such as AD conversion processing on the signal supplied from the amplification transistor 106 in this manner, to obtain a reset level corresponding to the high illuminance. Furthermore, the column processing unit 23 obtains a pixel signal corresponding to the high illuminance by obtaining a difference between the signal level and the reset level corresponding to the high illuminance, and supplies the pixel signal to the signal processing unit 28. Driving for obtaining the pixel signal corresponding to the high illuminance as described above is DDS driving.

On the basis of the respective pixel signals of the low illuminance, the medium illuminance, and the high illuminance for each unit pixel 62 supplied from the column processing unit 23 as described above, the signal processing unit 28 generates an image signal of one image and outputs to a subsequent stage.

At time t15, the vertical drive unit 22 brings the transfer transistor 104 into an OFF state to obtain a state in which the PD 92 and the capacitor 201 are electrically disconnected from the node 321.

At the following time t16, the vertical drive unit 22 brings the selection transistor 107 into an OFF state to bring the unit pixel 62 into a non-selected state. Furthermore, at time t17, the vertical drive unit 22 brings the reset transistor 105 into an ON state, to reset the FD 101 and the node 321.

At this time, after time t15 (period T7), the column processing unit 23 may read a signal from the unit pixel 62, that is, a signal according to charges accumulated in the FD 101 and the like, and the signal processing unit 28 may generate an image signal by a method called DOL, for example, on the basis of the read signal.

By performing the driving as described above, the CMOS image sensor 11 can generate one image with a wide dynamic range on the basis of multiple pixel signals corresponding to individual illuminance.

Note that, although the case where the unit pixel 62 has the configuration illustrated in FIG. 9 has been described here, driving similar to that in the example illustrated in FIG. 11 is performed also in a case where the unit pixel 62 has the configuration illustrated in FIG. 10. In this case, for example, at time t6 and time t8, the vertical drive unit 22 simultaneously brings the transfer transistors 102-1 to 102-4 into an ON state.

<Application Example to Electronic Device>

Note that the present technology is not limited to application to a solid-state imaging device. That is, the present technology can be applied to all electronic devices that use a solid-state imaging device as an image capture unit (photoelectric conversion unit), such as an imaging device such as a digital still camera or video camera, a mobile terminal device having an imaging function, or a copying machine using a solid-state imaging device for an image reading unit. The solid-state imaging device may be formed as a single chip, or may be formed as a module having an imaging function in which an imaging section and a signal processing unit or an optical system are packaged together.

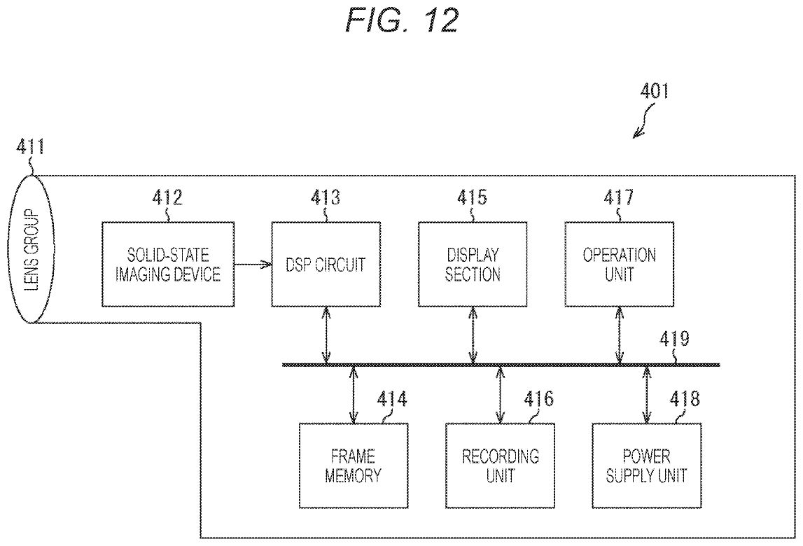

FIG. 12 is a block diagram illustrating a configuration example of an imaging device as an electronic device to which the present technology is applied.

An imaging device 401 in FIG. 12 includes an optical unit 411 including a lens group and the like, a solid-state imaging device (imaging device) 412 that adopts the configuration of the CMOS image sensor 11 in FIG. 1, and a digital signal processor (DSP) circuit 413 that is a camera signal processing circuit.

Furthermore, the imaging device 401 also includes a frame memory 414, a display section 415, a recording unit 416, an operation unit 417, and a power supply unit 418. The DSP circuit 413, the frame memory 414, the display section 415, the recording unit 416, the operation unit 417, and the power supply unit 418 are connected to one another via a bus line 419.

The optical unit 411 captures incident light (image light) from a subject and forms an image on an imaging surface of the solid-state imaging device 412. The solid-state imaging device 412 converts the light amount of the incident light imaged on the imaging surface by the optical unit 411 into an electrical signal in units of pixels and outputs the electrical signal as a pixel signal.

The display section 415 includes, for example, a thin display such as a liquid crystal display (LCD) or an organic electro luminescence (EL) display, and displays a moving image or a still image captured by the solid-state imaging device 412. The recording unit 416 records the moving image or the still image captured by the solid-state imaging device 412 on a recording medium such as a hard disk or a semiconductor memory.

The operation unit 417 issues operation commands for various functions of the imaging device 401 under operation by the user. The power supply unit 418 appropriately supplies various power sources serving as operation power sources of the DSP circuit 413, the frame memory 414, the display section 415, the recording unit 416, and the operation unit 417 to these supply targets.

<Usage Example of Image Sensor>

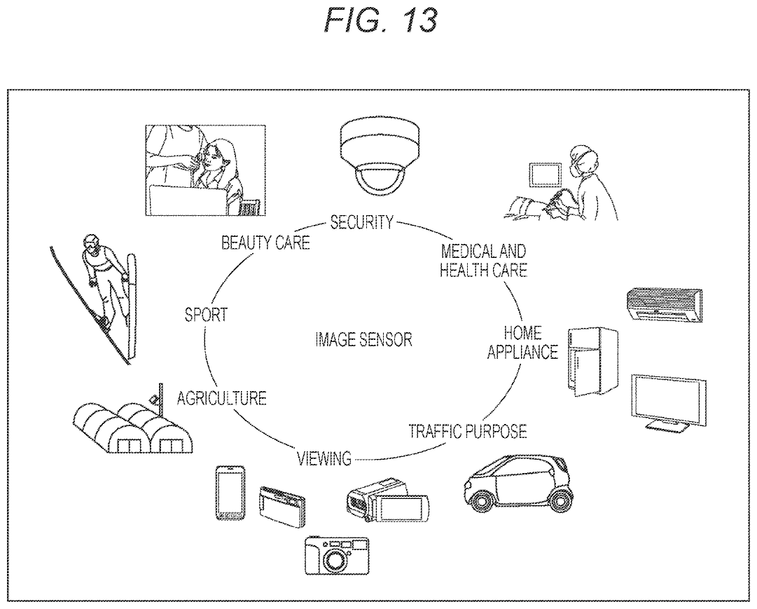

FIG. 13 is a diagram illustrating a usage example of the CMOS image sensor 11 described above.

The CMOS image sensor 11 described above can be used, for example, in various cases for sensing light such as visible light, infrared light, ultraviolet light, and X-rays as described below.
A device provided to be used for viewing, such as a digital camera or a portable device with a camera function, the device taking an image
A device for traffic purpose such as a vehicle-mounted sensor that takes images of the front, rear, surroundings, interior and the like of an automobile, a monitoring camera that monitors traveling vehicles and roads, and a ranging sensor that measures a distance between vehicles and the like for safe driving such as automatic stop, recognition of a driver's condition and the like
A device for home appliance such as a television, a refrigerator, and an air conditioner that images a user's gesture and performs device operation according to the gesture
A device for medical and health care use such as an endoscope and a device that performs angiography by receiving infrared light
A device for security use such as a security monitoring camera and an individual authentication camera
A device used for beauty care, such as a skin measuring instrument for photographing skin, and a microscope for photographing the scalp
A device used for sport, such as an action camera or a wearable camera for sports applications or the like
A device used for agriculture, such as a camera for monitoring a condition of a field or crop

<Application Example to Mobile Object>

As described above, the technology (the present technology) according to the present disclosure can be applied to various products. For example, the technology according to the present disclosure may also be achieved as a device mounted on any type of mobile object such as an automobile, an electric vehicle, a hybrid electric vehicle, a motorcycle, a bicycle, a personal mobility, an airplane, a drone, a boat, a robot, and the like.

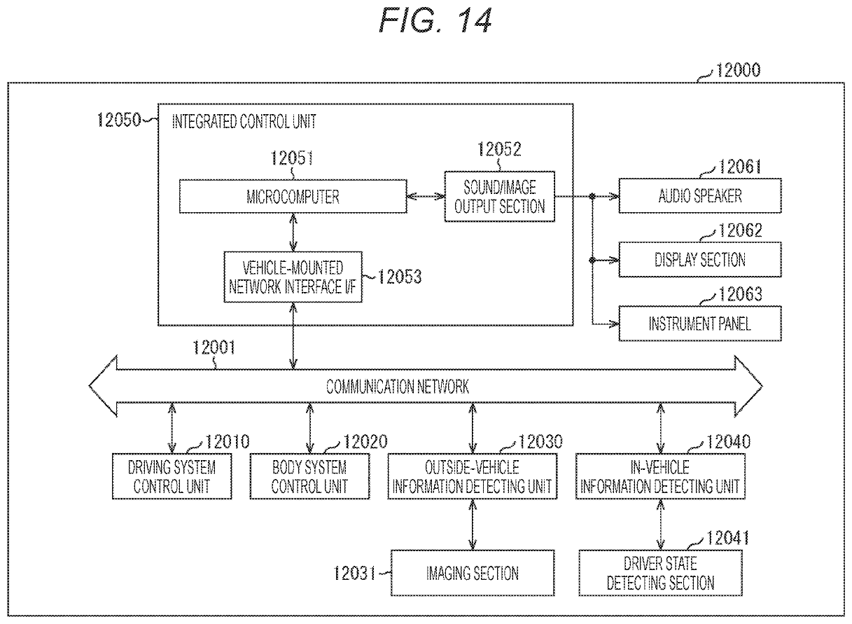

FIG. 14 is a block diagram illustrating a schematic configuration example of a vehicle control system that is an example of a mobile object control system to which the technology according to the present disclosure can be applied.

The vehicle control system 12000 includes a plurality of electronic control units connected to each other via a communication network 12001. In the example depicted in FIG. 14, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 14, an audio speaker 12061, a display section 12062, and an instrument panel 12063 are illustrated as output devices. The display section 12062 may, for example, include at least one of an on-board display and a head-up display.

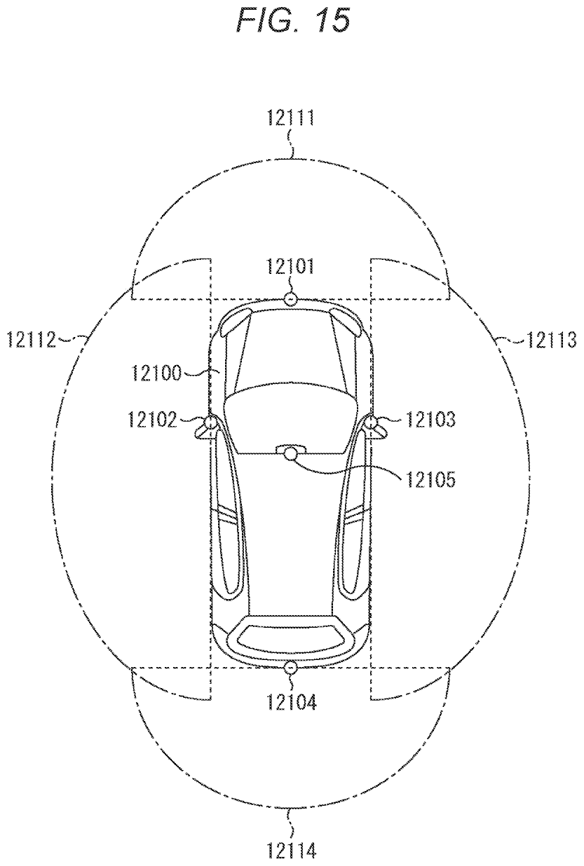

FIG. 15 is a diagram illustrating an example of an installation position of the imaging section 12031.

In FIG. 15, a vehicle 12100 includes imaging sections 12101, 12102, 12103, 12104, and 12105 as the imaging section 12031.

The imaging sections 12101, 12102, 12103, 12104, and 12105 are, for example, provided at positions on a front nose, sideview mirrors, a rear bumper, and a back door of the vehicle 12100 as well as a position on an upper portion of a windshield in the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 15 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technique according to the present disclosure can be applied to the imaging section 12031 and the like in the configuration described above. Specifically, for example, the CMOS image sensor 11 illustrated in FIG. 1 can be used as the imaging section 12031, and an image with a wide dynamic range can be obtained.

Note that, the present technology is not limited to application to a solid-state imaging device that detects distribution of the amount of incident light of visible light and captures the distribution as an image, and can be applied to all solid-state imaging devices (physical quantity distribution detection devices) such as a solid-state imaging device that captures distribution of the amount of incident infrared rays, X-rays, particles, or the like as an image, a fingerprint detection sensor that detects distribution of other physical quantities such as pressure, capacitance, and the like, and captures the distribution as an image in a broad sense, and the like.

Furthermore, the present technology can be applied not only to solid-state imaging devices but also to general semiconductor devices having other semiconductor integrated circuits.

The embodiment of the present technology is not limited to the above-described embodiment, and various modifications can be made without departing from the scope of the present technology.

For example, a form in which all or some of the plurality of embodiments described above are combined can be adopted.

Furthermore, the effects described in the present specification are merely examples and are not limited, and effects other than those described in the present specification may be provided.

Moreover, the present technology may also have a following configuration.

(1)

A solid-state imaging device including:
a pixel array unit provided with multiple unit pixels, in which
each of the unit pixels includes:
   a small pixel having a first photoelectric conversion unit and a first on-chip lens configured to allow light to enter the first photoelectric conversion unit; and
   a large pixel having a second photoelectric conversion unit divided into multiple regions, and a second on-chip lens capable of condensing more light than the first on-chip lens, the second on-chip lens being configured to allow light to enter the second photoelectric conversion unit.

(2)

The solid-state imaging device according to (1), in which
the second photoelectric conversion unit is divided into the multiple regions by a P-type impurity region.

(3)

The solid-state imaging device according to (1), in which
the second photoelectric conversion unit is divided into the multiple regions by an N-type impurity region.

(4)

The solid-state imaging device according to (1), in which
the second photoelectric conversion unit is divided into the multiple regions by an insulator.

(5)

The solid-state imaging device according to any one of (1) to (4), further including:
multiple transfer gates configured to transfer charges obtained in the multiple regions.

(6)

The solid-state imaging device according to any one of (1) to (5), further including:
a first capacitor connected to the first photoelectric conversion unit.

(7)

The solid-state imaging device according to (6), in which
the first capacitor is an MIM.

(8)

The solid-state imaging device according to any one of (1) to (7), further including:
a charge holding unit configured to hold a charge transferred from the first photoelectric conversion unit or the second photoelectric conversion unit; and
a second capacitor connected to the charge holding unit.

(9)

The solid-state imaging device according to (8), in which
the second capacitor is an MIM.

(10)

The solid-state imaging device according to any one of (1) to (9), further including:
a charge holding unit configured to hold a charge transferred from the first photoelectric conversion unit or the second photoelectric conversion unit; and
multiple amplification transistors connected in parallel and configured to output a signal corresponding to a charge held in the charge holding unit.

(11)

An electronic device including:
a solid-state imaging device including
a pixel array unit provided with multiple unit pixels, in which
each of the unit pixels includes:
   a small pixel having a first photoelectric conversion unit and a first on-chip lens configured to allow light to enter the first photoelectric conversion unit; and
   a large pixel having a second photoelectric conversion unit divided into multiple regions, and a second on-chip lens capable of condensing more light than the first on-chip lens, the second on-chip lens being configured to allow light to enter the second photoelectric conversion unit.

### REFERENCE SIGNS LIST

11 CMOS image sensor
21 Pixel array unit
22 Vertical drive unit
23 Column processing unit
28 Signal processing unit
62 Unit pixel
71 Large pixel
72 Small pixel
81 On-chip lens
82 On-chip lens
83 P-type impurity region
93a to 93d, 93 PD
131 Insulator
161a to PD 161d, 161 PD
261 Capacitor
291 Capacitor

What is claimed is:

1. A solid-state imaging device comprising:
a pixel array unit provided with multiple unit pixels, wherein
each of the unit pixels includes:
a small pixel having a first photoelectric conversion unit and a first on-chip lens configured to allow light to enter the first photoelectric conversion unit; and
a large pixel having a second photoelectric conversion unit divided into multiple regions, and a second on-chip lens capable of condensing more light than the first on-chip lens, the second on-chip lens being configured to allow light to enter the second photoelectric conversion unit.

2. The solid-state imaging device according to claim 1, wherein
the second photoelectric conversion unit is divided into the multiple regions by a P-type impurity region.

3. The solid-state imaging device according to claim 1, wherein
the second photoelectric conversion unit is divided into the multiple regions by an N-type impurity region.

4. The solid-state imaging device according to claim 1, wherein
the second photoelectric conversion unit is divided into the multiple regions by an insulator.

5. The solid-state imaging device according to claim 1, further comprising:
multiple transfer gates configured to transfer charges obtained in the multiple regions.

6. The solid-state imaging device according to claim 1, further comprising:
a first capacitor connected to the first photoelectric conversion unit.

7. The solid-state imaging device according to claim 6, wherein
the first capacitor includes an MIM.

8. The solid-state imaging device according to claim 1, further comprising:
a charge holding unit configured to hold a charge transferred from the first photoelectric conversion unit or the second photoelectric conversion unit; and
a second capacitor connected to the charge holding unit.

9. The solid-state imaging device according to claim 8, wherein
the second capacitor includes an MIM.

10. The solid-state imaging device according to claim 1, further comprising:
a charge holding unit configured to hold a charge transferred from the first photoelectric conversion unit or the second photoelectric conversion unit; and
multiple amplification transistors connected in parallel and configured to output a signal corresponding to a charge held in the charge holding unit.

11. An electronic device, comprising:
a solid-state imaging device including
a pixel array unit provided with multiple unit pixels, wherein
each of the unit pixels includes:
a small pixel having a first photoelectric conversion unit and a first on-chip lens configured to allow light to enter the first photoelectric conversion unit; and
a large pixel having a second photoelectric conversion unit divided into multiple regions, and a second on-chip lens capable of condensing more light than the first on-chip lens, the second on-chip lens being configured to allow light to enter the second photoelectric conversion unit.
